(19) United States
(12) Patent Application Publication
(10) Pub. No.: US 2012/0189842 A1
(43) Pub. Date: Jul. 26, 2012

(54) ELECTRONIC DEVICE HOUSING AND METHOD FOR MAKING THE SAME

(75) Inventors: QI-JIAN DU, ShenZhen City (CN); CHWAN-HWA CHIANG, Shindian (TW)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/207,100

(22) Filed: Aug. 10, 2011

(30) Foreign Application Priority Data
Jan. 22, 2011 (CN) 201110024471.2

(51) Int. Cl. B32B 3/00; C23C 14/08; B32B 17/06; B32B 15/04; B32B 27/40; C23C 14/34; C23C 14/14

(52) U.S. Cl. 428/336; 204/192.1; 428/457; 428/425.8; 428/432

(57) ABSTRACT

An electronic device includes a substrate, a metallic coating formed on the substrate by vacuum sputtering or vacuum vapor deposition and a top paint coating formed on the metallic coating. The metallic coating comprising a plurality of titanium oxide layers interleaved with an equal number of silicon oxide layers and has a reflectively of about 50%-80%. The top paint coating includes pearl pigments.

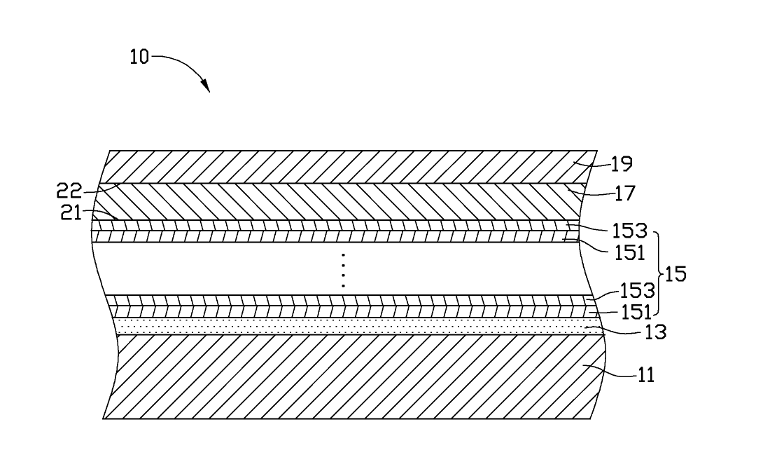

### BACKGROUND

1. Technical Field

The present disclosure relates to electronic device housings, particularly to an electronic device housing having a metallic and color changeable appearance, and a method for making the electronic device housing.

2. Description of Related Art

Decorative metallic coatings are often deposited on housings of electronic devices. The metallic coatings are typically formed by vacuum deposition to be nonconductive so as to not block the electromagnetic waves. These metallic coatings may be transparent or translucent. However, the metallic coatings cannot present a color changeable appearance.

Therefore, there is room for improvement within the art.

### BRIEF DESCRIPTION OF THE FIGURES

Many aspects of the electronic device housing can be better understood with reference to the following FIGURE. The components in the FIGURES are not necessarily drawn to scale, the emphasis instead being placed upon clearly illustrating the principles of the electronic device housing

The FIGURE is a cross-section of an electronic device housing according to an exemplary embodiment.

### DETAILED DESCRIPTION

The FIGURE shows an electronic device housing 10 according to an exemplary embodiment. The electronic device housing 10 includes a substrate 11, a base paint coating 13 formed on a surface of the substrate 11, a metallic coating 15 formed on the base paint coating 13, a middle paint coating 17 formed on the metallic coating 15, and a top paint coating 19 formed on the middle paint coating 17.

The electronic device housing 10 may be a housing of a mobile phone, personal digital apparatus (PDA), notebook computer, MP3 player, GPS navigator, or a digital camera.

The substrate 11 may be made of plastic material selected from a group consist of polycarbonate (PC), polyethylene (PE), polymethyl methacrylate (PMMA), and a mixture of polycarbonate and acrylonitrile-butadiene-styrene plastics (PC+ABS). The substrate 11 may also be made of ceramic or glass.

The base paint coating 13 may be a polyurethane resin paint coating. The base paint coating 13 may be transparent and have a thickness of about 5 μm-10 μm. The base paint coating 13 has a smooth surface for enhancing the bond between the base paint coating 13 and subsequent coatings.

The metallic coating 15 may be formed on the base paint coating 13 by vacuum sputtering or vacuum vapor deposition. The metallic coating 17 has a metallic appearance. The metallic coating 15 may includes a plurality of titanium oxide (TiO₂) layers 151 alternating with an equal number of silicon oxide (SiO₂) layers 153. The metallic coating 15 may comprise three to seven layers. Either one titanium oxide layer 151 or a silicon oxide layer 153 may be directly formed on the base paint coating 13. The total thickness of the metallic coating 15 may be of about 50 nm-500 nm. The thickness of the metallic coating 15 is controlled to present a metallic appearance for the electronic device housing 10 without interfering with radio transmission capabilities.

The middle paint coating 17 has a thickness of about 10 μm-50 μm. The middle paint coating 17 may be an ultraviolet (UV) curable resin paint coating or a thermosetting paint coating. The paint used for the thermosetting paint coating is selected form polyurethane resin paint and unsaturated polyester, preferably, polyurethane resin paint. The middle paint coating 17 can enhance the bond between the base paint coating 13 and the top paint coatings 19.

The top paint coating 19 may be a transparent paint coating formed on the middle paint coating 17. The paint used for the top paint coating 19 may be polyurethane resin paint. The polyurethane resin paint includes pearl pigments, wherein the mass percentage of pearl pigments is about 1%-3%. The particle diameter of the pearl pigments is 200 nm-900 nm. The thickness of the top paint coating 19 may be about 20 μm-30 μm. The top paint coating 19 has a high hardness that can protect the metallic coating 15 and the middle paint coating 17 from abrasion damage.

The electronic device housing 10 further includes a first surface 21 and an opposite second surface 22. The first surface 21 is positioned between the metallic coating 15 and the middle paint coating 17, and the second surface 22 is positioned between the middle paint coating 17 and top paint coating 19.

It is to be understood that the base paint coating 13 may be omitted, and the metallic coating 15 can be directly formed on the substrate 11.

The middle paint coating 17 is applied as a bonding agent between the metallic coating 15 and the paint coating 19 but may be omitted, and the top coating 19 can be directly formed on the metallic coating 15.

The pearl pigments of the top paint coating 19 diffuse light under irradiation of visible light at different incident angles. The scattered light refracted by the first surface 21 and the second surface 22 caused by the different refractive index of the metallic coating 15, the middle paint coating 17 and the top paint coating 19. The scattered light also reflected by the first surface 21 and the second surface 22. The light refracted and/or reflected by the first surface 21 has different wavelength than the light refracted and/or by the second surface 22, and these different wavelengths form several intensifying interference regions. The different intensifying interference regions, when viewed by a user during relative movement between the user and the electronic device housing 10, will make the electronic device housing 10 to have a pearlescent and color changeable appearance.

Because there is a large difference between the refractive index of the titanium oxide layers 151 (of about 1.9-2.0 refractivity) and the refractive index of the silicon oxide layers 153 (of about 1.42-1.46 refractivity), the metallic coating 15 has a reflectivity of about 50%-80%. The light reflected by the titanium oxide layers 151 has different wavelength from the silicon oxide layers 153, cooperatively forming several intensifying interference regions. The different intensifying interference regions, when viewed by a user during relative movement between the user and the electronic device housing 10, gives off difference metallic color appearnaces.

A method for making the electronic device housing 10 may include the following steps.

The substrate 11 is provided. The substrate 11 may be made of plastic, glass, ceramic, or metal. The substrate 11 is cleaned by a cleaning solution to remove grease from the surface of the substrate 11. The cleaning solution can be ethanol, acetone and/or other organic solvents. A common ultrasonic cleaning machine can be used for cleaning the substrate 11.

The base paint coating 13 is sprayed on the substrate 11. The base paint coating 13 may be transparent and have a thickness of about 5 μm-10 μm.

The metallic coating 15 is formed on the base paint coating 13 by vacuum sputtering or vacuum vapor deposition. During deposition of the titanium oxide layers 151, the titanium target is used, and oxygen (O₂) may be used as a reaction gas. During deposition of the silicon oxide layers 153, the silicon oxide target is used, and oxygen may be used to supplement oxygen (O) lost during deposition of the silicon oxide layers 153. The thickness of the metallic coating 15 is controlled to present a metallic appearance for the electronic device housing 10 without interfering with radio transmission capabilities. The total thickness of the metallic coating 15 may be about 50 nm-500 nm.

The middle paint coating 17 is sprayed on the metallic coating 15. The middle paint coating 17 may be an ultraviolet (UV) curable resin paint coating or a thermosetting paint coating. The paint used for the thermosetting paint coating is selected form polyurethane resin paint and unsaturated polyester.

The top paint coating 19 is sprayed on middle paint coating 17. The paint used for the top paint coating 19 may be a polyurethane resin paint. The polyurethane resin paint includes pearl pigments, wherein the mass percentage of pearl pigments is about 1%-3%.

It should be understood, however, that though numerous characteristics and advantages of the present embodiments have been set forth in the foregoing description, together with details of functions of the embodiments, the disclosure is illustrative only, and changes may be made in detail within the principles of the disclosure to the full extent indicated by the broad general meaning of the terms in which the appended claims are expressed.

What is claimed is:

1. An electronic device housing, comprising:
a substrate; and
a metallic coating formed on the substrate by vacuum sputtering or vacuum vapor deposition, the metallic coating including a plurality of titanium oxide layers alternating with an equal number of silicon oxide layers and having a reflectivity of about 50%-80%; and
a top paint coating formed on the metallic coating, the top paint coating including pearl pigments.

2. The electronic device housing as claimed in claim 1, wherein the metallic coating has a thickness of about 50 nm-500 nm.

3. The electronic device housing as claimed in claim 1, wherein the top paint coating has a thickness of about 20 μm-30 μm.

4. The electronic device housing as claimed in claim 1, wherein the top paint coating is a polyurethane resin paint coating, wherein the mass percentage of pearl pigments is about 1-3%.

5. The electronic device housing as claimed in claim 1, wherein the metallic coating comprise three to seven layers.

6. The electronic device housing as claimed in claim 1, wherein each titanium oxide layer has a refractivity index of about 1.9-2.0, and each silicon oxide layer has a refractivity index of about 1.42-1.46.

7. The electronic device housing as claimed in claim 1, further comprising a middle paint coating formed between the metallic coating and the top paint coating.

8. The electronic device housing as claimed in claim 7, wherein middle paint coating has a thickness of about 10 μm-50 μm.

9. The electronic device housing as claimed in claim 7, wherein the middle paint coating is an ultraviolet curable resin paint coating or a thermosetting paint coating.

10. The electronic device housing as claimed in claim 9, wherein the paint used for the thermosetting paint coating is selected form polyurethane resin paint and unsaturated polyester.

11. The electronic device housing as claimed in claim 1, wherein the substrate is made of plastic, ceramic or glass.

12. The electronic device housing as claimed in claim 1, further comprising a base paint coating formed between the substrate and the metallic coating.

13. The electronic device housing as claimed in claim 12, wherein the base paint coating has a thickness of about 5 μm-10 μm.

14. A method for making electronic device housing, comprising:
providing a substrate;
vacuum sputtering or vacuum vapor depositing a metallic coating on the substrate, the metallic coating including a plurality of titanium oxide layers alternating with an equal number of silicon oxide layers and having a reflectively of about 50%-80%;
spraying a top paint coating on the metallic coating, the top paint coating includes pearl pigments.

15. The method as claimed in claim 14, wherein during deposition of the titanium oxide layers use the titanium target, and the oxygen used as a reaction gas.

16. The method as claimed in claim 14, wherein during deposition of the silicon oxide layers use the silicon oxide target, and oxygen is used to supplement element oxygen lost during deposition of the silicon oxide layers.

17. The method as claimed in claim 14, further comprising a step of spraying a base paint coating on the substrate before forming the metallic coating.

18. The method as claimed in claim 14, further comprising a step of spraying a middle paint coating between the metallic coating and the top paint coating.
